(19) United States
(12) Patent Application Publication
(10) Pub. No.: US 2012/0081000 A1
(43) Pub. Date: Apr. 5, 2012

(54) LED ENCAPSULATION PROCESS AND SHIELD STRUCTURE MADE THEREBY

(75) Inventors: CHIEN-YUAN CHEN, TAIPEI CITY (TW); YI-SHENG CHEN, TAIPEI CITY (TW)

(73) Assignee: POWER DATA COMMUNICATIONS CO., LTD., TAIPEI COUNTY (TW)

(21) Appl. No.: 12/897,961

(22) Filed: Oct. 5, 2010

(51) Int. Cl. H01L 33/52

(52) U.S. Cl. 313/501

(57) ABSTRACT

The present invention discloses an LED encapsulation process and a shield structure made thereby. Firstly, a first encapsulation layer is provided, phosphor powder is uniformly disposed on a surface of the first encapsulation layer, and a second encapsulation layer is disposed on the phosphor powder to fully cover the first encapsulation layer so that the phosphor powder is sandwiched between the two encapsulation layers to ensure its arrangement position. Finally, the aforementioned members are heated and stamped to form one piece which is cut into a required shield shape.

### 1. FIELD OF THE INVENTION

The present invention relates to the field of manufacture technology of light-emitting diodes, and more particularly to a process in which two-stage encapsulation is utilized to ensure the arrangement position of phosphor powder and then molding is used to form a shield and its structure made thereby.

### 2. DESCRIPTION OF THE RELATED ART

A conventional LED structure, as shown in FIG. 1, mainly comprises a base 60, wherein the base 60 comprises a leadframe, positive and negative electrodes that are relatively spaced apart at a certain distance, and legs at the lower portion. A chip is mounted on the positive or negative electrode, gold wires are bonded from the chip to the opposite electrode, and then they are covered by epoxy resin encapsulation 70. Phosphor powder 80 is doped within the encapsulation 70. When the light emitted by the chip hits the phosphor powder 80 in the encapsulation 70, different colors are generated due to the different formulations of the phosphor powder 80.

However, the encapsulation 70 containing the phosphor powder 80 is sealed on top of the base 60 and needs time to gradually solidify to form a complete LED. During the period the encapsulation 70 gradually solidifies, the phosphor powder 80 will gradually sink or move towards the bottom due to its own weight and/or the kinetic energy generated when the encapsulation 70 is coated, so that the phosphor powder 80 can not be uniformly distributed within the encapsulation 70, even resulting in some distributions like colonies, which leads to the disadvantage of reduced light flux of an LED, uneven color temperature of the same color light emitting diodes (LEDs) and poor color saturation. This is a bottleneck of the conventional encapsulation technology.

As shown in FIG. 2, SMT-type LEDs have also been designed. However, in such LED structure, there also exists the problem that the phosphor powder 80′ cannot be uniformly distributed within the encapsulation 70′, thereby leading to the disadvantage of reduced light flux of an LED, uneven color temperature of the same color LEDs and poor color saturation. Both of them are the bottlenecks faced by the industry, and eager to be overcome.

### SUMMARY OF THE INVENTION

In view of the above-mentioned shortcomings of the prior art, an object of the present invention is to provide an LED encapsulation process and a shield structure made thereby, in which the arrangement position of phosphor powder can be maintained.

To achieve the foregoing object, the present invention provides an LED encapsulation process and a shield structure made thereby. The LED encapsulation process comprises the following steps: providing a first encapsulation layer; disposing phosphor powder on a surface of the first encapsulation layer so that the phosphor powder is uniformly distributed on the first encapsulation layer; disposing a second encapsulation layer on the phosphor powder, the second encapsulation layer fully covering the first encapsulation layer so that the phosphor powder is sandwiched between the first encapsulation layer and the second encapsulation layer; heating and stamping the first encapsulation layer, the phosphor powder and the second encapsulation layer to form one piece, or alternatively thermally compressing the first encapsulation layer and the second encapsulation layer; and cutting the piece formed of the first encapsulation layer, the phosphor powder and the second encapsulation layer to form an LED shield.

In this embodiment, the first encapsulation layer and the second encapsulation layer are made of silicone, or are other equivalent encapsulation layers. In the step of providing the first encapsulation layer, liquid silicone is coated on a model and cured to form a thin film-type first encapsulation layer. Furthermore, in the step of disposing the second encapsulation layer on the phosphor powder, liquid silicone is coated on a model and cured to form a thin film-type second encapsulation layer, and then the second encapsulation layer is covered on the surface of the first encapsulation layer with the phosphor powder; or in the step of disposing the second encapsulation layer on the phosphor powder, liquid silicone is coated on the surface of the first encapsulation layer with the phosphor powder. Moreover, in the step of heating and stamping, the outer side surface of the shield is pressed annularly to form a reflecting structure for guiding the direction and angle of light projection.

To achieve the foregoing object, a shield structure made by the aforementioned LED encapsulation process comprises: a first encapsulation layer; phosphor powder uniformly distributed on a surface of the first encapsulation layer; and a second encapsulation layer covering the first encapsulation layer so that the phosphor powder is sandwiched between the first encapsulation layer and the second encapsulation layer. The first encapsulation layer and the second encapsulation layer are made of silicone, or are other equivalent encapsulation layers. Furthermore, the outer side annular surface of the second encapsulation layer of the shield has a reflecting structure for guiding the direction and angle of light projection.

As compared with the prior art, in the present invention, the first encapsulation layer and the second encapsulation layer are disposed stepwise to ensure that the phosphor powder can be uniformly distributed between the two encapsulation layers, and then a thin film of the two layers is compressed to form a shield structure, which is advantageous to be used for sealing at any time in an LED process. Therefore, according to the present invention, the position of the phosphor powder can be maintained without floating or deviation during the forming process. This enables increased light flux in an LED, uniform color temperature of the same color LEDs and improved color saturation. Hence, the present invention is an innovational encapsulation technology indeed.

### BRIEF DESCRIPTION OF THE DRAWINGS

FIG. 1 is a schematic view showing a structure of a first conventional LED;

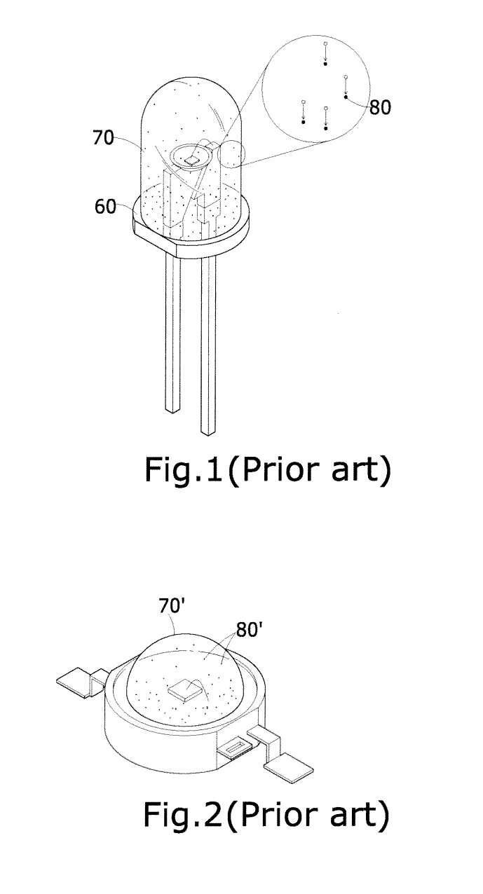

FIG. 2 is a schematic view showing a structure of a second conventional LED;

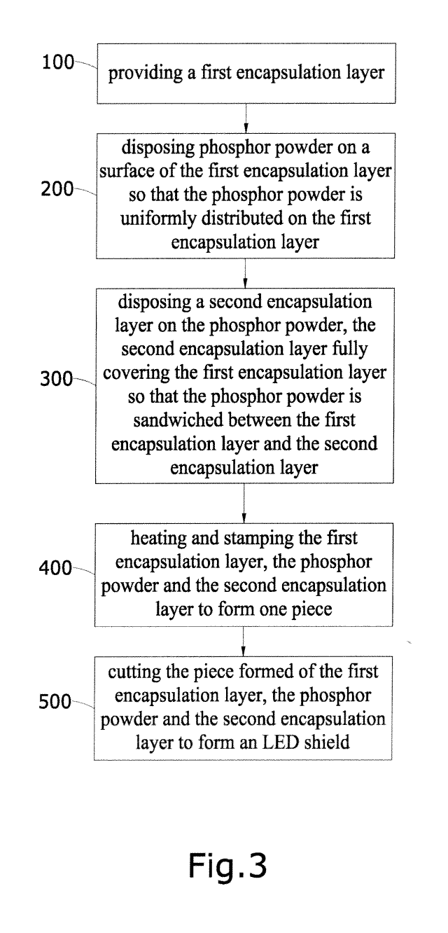

FIG. 3 is a block flow chart of a preferred embodiment according to the present invention;

FIGS. 4a to 4g are schematic views corresponding to the steps of a preferred embodiment according to the present invention; and

FIGS. 5a to 5e are schematic views corresponding to the steps of another preferred embodiment according to the present invention.

### DETAILED DESCRIPTION OF THE PREFERRED EMBODIMENTS

The contents of the present invention will become more apparent from the following description when taken in conjunction with the drawings.

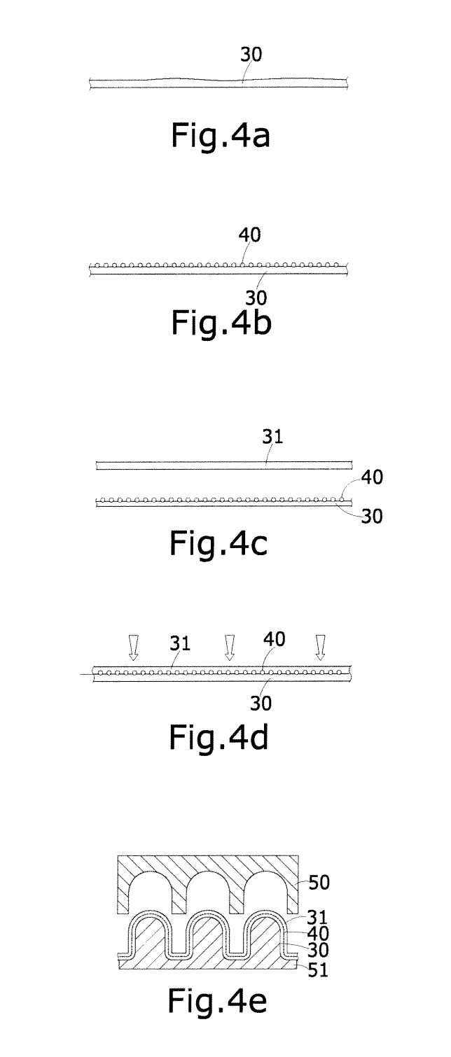

Referring to FIG. 3, there is shown a block flow chart of a preferred embodiment according to the present invention. As shown in FIG. 3, an LED encapsulation process of the present invention comprises the following steps: step 100, providing a first encapsulation layer; step 200, disposing phosphor powder on a surface of the first encapsulation layer so that the phosphor powder is uniformly distributed on the first encapsulation layer; step 300, disposing a second encapsulation layer on the phosphor powder, the second encapsulation layer fully covering the first encapsulation layer so that the phosphor powder is sandwiched between the first encapsulation layer and the second encapsulation layer; step 400, heating and stamping the first encapsulation layer, the phosphor powder and the second encapsulation layer to form one piece; and step 500, cutting the piece formed of the first encapsulation layer, the phosphor powder and the second encapsulation layer to form an LED shield.

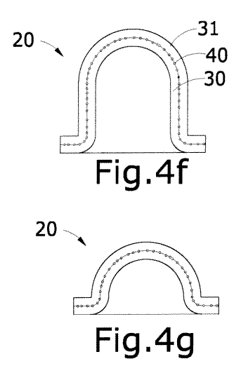

Simultaneously referring to FIGS. 4a to 4g, there are shown schematic views corresponding to the steps of a preferred embodiment according to the present invention. As shown in FIG. 4a, which corresponds to the above-mentioned first step 100, when a first encapsulation layer 30 is provided, a thin film formed by such as silicone is used as the first encapsulation layer 30. Liquid silicone is coated on a model and cured to form a thin film-type first encapsulation layer 30. It should be noted that during the coating of liquid silicone in the step of providing first encapsulation layer, the finishing and flattening procedures are performed to obtain a flat surface.

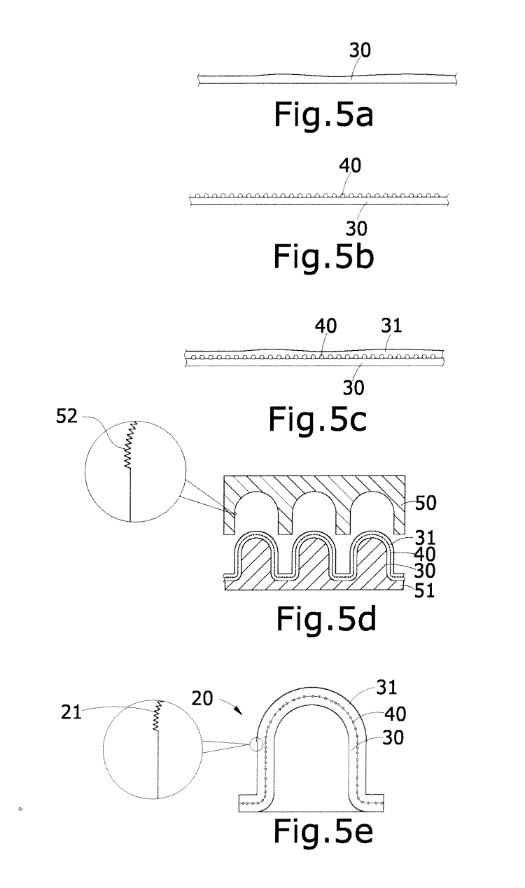

Next, as shown in FIG. 4b, which corresponds to the second step 200, phosphor powder 40 is disposed on a surface of the first encapsulation layer 30 so that the phosphor powder 40 is uniformly distributed on the first encapsulation layer 30, also as shown in FIG. 5b. One of ordinary skill in the art can easily understand the technology and equipment for uniformly disposing the phosphor layer 40 on the surface of the first encapsulation layer 30, which will be described in no more detail.

Afterwards, as shown in FIG. 4c, which corresponds to the third step 300, a second encapsulation layer 31 is disposed on the phosphor powder 40, and the second encapsulation layer 31 fully covers the first encapsulation layer 30 so that the phosphor powder 40 is sandwiched between the first encapsulation layer 30 and the second encapsulation layer 31. It should be noted that, in the first embodiment, a thin film formed by such as silicone is similarly used as the second encapsulation layer 31. Liquid silicone is coated on a model and cured to form a thin film-type second encapsulation layer 31, and the formed second encapsulation layer 31 is fully covered on the surface of the first encapsulation layer 30 with the phosphor powder 40. Certainly, the second sealing layer 31 is similarly flattened and finished to obtain a flat surface. Furthermore, as shown by the arrows in FIG. 4d, in this step, the first encapsulation layer 30 and the second encapsulation layer 31 can be heated and stamped so that both of them are bonded with each other into one piece. When the first encapsulation layer 30 and the second encapsulation layer 31 are bonded with each other by thermal compression, the arrangement position of the phosphor powder 40 uniformly distributed therebetween is fixed.

Then, as shown in FIG. 4e, which corresponds to the fourth step 400, the first encapsulation layer 30, the phosphor powder 40 and the second encapsulation layer 31 are heated and stamped to form one piece. The first encapsulation layer 30 and the second encapsulation layer 31 with the phosphor powder 40 sandwiched therebetween are placed between the molds 50,51 followed by stamping , for example, to form a predetermined lens structure.

Finally, as shown in FIG. 4f, which corresponds to the fourth step 400, the piece formed of the first encapsulation layer 30, the phosphor powder 40 and the second encapsulation layer 31 is cut to form an LED shield 20, for example, the cylindrical shield 20 as shown in FIG. 4f, which comprises the first encapsulation layer 30 and the second encapsulation layer 31 with the phosphor powder 40 sandwiched therebetween. It should be noted that, as shown in FIG. 4g, if the molds 50,51 of different shapes are used, the shield 20 can be molded into different shapes, for example, the circular arc-shaped shield 20 as shown in FIG. 4g. In other words, if the shapes of the molds 50,51 used in stamping are changed or the cutting shapes are changed, the shields 20 of different shapes such as conical, prominent grain or cubic shapes can be made, which may be implemented by one of ordinary skill in the art using the concept of this embodiment and will be described and illustrated in no more detail, to provide various shields 20 for sealing chips in an LED process.

Simultaneously referring to FIG. 3 and FIGS. 5a to 5f, there are shown schematic views corresponding to the steps of another preferred embodiment according to the present invention. As shown in these figures, the portions of this embodiment which are the same as or similar to that of the former embodiment have the same reference numerals and therefore explanation of such elements is omitted. However, the structure of the second encapsulation layer is changed, which is slightly different in the implementation of the process.

As the same as the former embodiment, the first step 100 is as shown in FIG. 5a, in which a first encapsulation layer 30 is provided.

The first step 200 is as shown in FIG. 5b, in which phosphor powder 40 is similarly disposed on the first encapsulation layer 30 so that the phosphor powder 40 is uniformly distributed on a surface of the first encapsulation layer 30.

The first step 300 is as shown in FIG. 5c. However, in this step, liquid silicone is used as the second encapsulation layer 31 and uniformly coated on the surface of the first encapsulation layer 30 with the phosphor powder 40 disposed thereon so that the second encapsulation layer 31 fully covers the first encapsulation layer 30. After the second encapsulation layer 31 is cured, the phosphor powder 40 is similarly uniformly sandwiched between the first encapsulation layer 30 and the second encapsulation layer 31. It should be noted that after the second encapsulation layer 31 is cured, it still requires the flattening and finishing procedures to obtain a flat surface.

The fourth step 400 is as shown in FIG. 5d, in which the aforementioned first encapsulation layer 30, phosphor powder 40 and second encapsulation layer 31 are placed between two molds 50 and 51 followed by heating and stamping.

Finally, the fifth step 500 is as shown in FIG. 5e, in which the first encapsulation layer 30, the phosphor powder 40 and the second encapsulation layer 31 after stamping can also be cut to form an LED shield 20.

It should be noted that in stamping of the shield 20, a reflecting structure 21 is formed on the periphery of its outer side surface to guide the direction and angle of light projection. The angle can be set to 30 degrees, 60 degrees or 90 degrees based on actual requirements, so that the light can be projected in an appropriate range of angles. Moreover, since the inner surface of the mold 50 has appropriate embossed patterns 52, when in stamping process, the reflecting structure 21 with patterns will be formed on the surface of the second encapsulation layer 31.

In summarization of the foregoing description, the two encapsulation layers 30, 31 are used to sandwich the phosphor powder 40 in manufacturing the shield 20, so as to maintain the position of the phosphor powder 40 without floating or deviation during the forming process. This enables increased light flux in an LED, uniform color temperature of the same color LEDs and improved color saturation, which are the advantages when the shield 20 structure of the present invention is in use.

However, what are described above are only preferred embodiments of the invention and should not be used to limit the claims of the present invention, and therefore all equivalent substitutions and modifications such as changes in the material or number of the encapsulation layers or changes in the shape of the shield, can made without departing from the spirit and scope of the present invention should be included in the appended claims.

What is claimed is:

1. An LED encapsulation process, comprising the following steps:
providing a first encapsulation layer;
disposing phosphor powder on a surface of the first encapsulation layer so that the phosphor powder is uniformly distributed on the first encapsulation layer;
disposing a second encapsulation layer on the phosphor powder, the second encapsulation layer fully covering the first encapsulation layer so that the phosphor powder is sandwiched between the first encapsulation layer and the second encapsulation layer;
heating and stamping the first encapsulation layer, the phosphor powder and the second encapsulation layer to form one piece; and
cutting the piece formed of the first encapsulation layer, the phosphor powder and the second encapsulation layer to form in an LED shield.

2. The LED encapsulation process of claim 1, wherein the first encapsulation layer and the second encapsulation layer are made of silicone.

3. The LED encapsulation process of claim 1, wherein in the step of providing the first encapsulation layer, liquid silicone is coated on a model and cured to form a thin film-type first encapsulation layer.

4. The LED encapsulation process of claim 1, wherein in the step of disposing the second encapsulation layer, on the phosphor powder, liquid silicone is coated on a model and cured to form a thin film-type second encapsulation layer, and then the second encapsulation layer is covered on the surface of the first encapsulation layer with the phosphor powder.

5. The LED encapsulation process of claim 1, wherein in the step of disposing the second encapsulation layer on the phosphor powder, liquid silicone is coated on the surface of the first encapsulation layer with the phosphor powder.

6. The LED encapsulation process of claim 1, wherein in the step of heating and stamping, the outer side surface of the shield is pressed annularly to form a reflecting structure for guiding the direction and angle of light projection.

7. An LED shield structure, comprising:
a first encapsulation layer;
phosphor powder uniformly distributed on a surface of the first encapsulation layer; and
a second encapsulation layer covering the first encapsulation layer so that the phosphor powder is sandwiched between the first encapsulation layer and the second encapsulation layer.

8. The LED shield structure of claim 7, wherein the first encapsulation layer and the second encapsulation layer are made of silicone.

9. The LED shield structure of claim 7, wherein the outer side annular surface of the second encapsulation layer of the shield has a reflecting structure for guiding the direction and angle of light projection.
